(19) United States
(12) Patent Application Publication
(10) Pub. No.: US 2026/0292970 A1
(43) Pub. Date: Sep. 24, 2026

(54) SUBSTRATE AND ELECTRONIC DEVICE

(71) Applicant: Kioxia Corporation, Tokyo (JP)

(72) Inventors: Yuma NOMURA, Hiratsuka (JP); Yuta TSUBOUCHI, Tokyo (JP)

(73) Assignee: Kioxia Corporation, Tokyo (JP)

(21) Appl. No.: 19/325,860

(22) Filed: Sep. 11, 2025

(30) Foreign Application Priority Data
Mar. 21, 2025 (JP) 2025-047258

(51) Int. Cl. H05K 1/02; H05K 1/11; H05K 1/18

(52) U.S. Cl. CPC H05K 1/0242; H05K 1/116; H05K 1/181; H05K 2201/09227; H05K 2201/09236; H05K 2201/10159; H05K 2201/10212

(57) ABSTRACT

According to one embodiment, a substrate includes a a base; and a transmission line disposed on or in a base, and formed as a part of a plurality of conductor layers. The transmission line includes: a first conductor line disposed in a first one of the conductor layers; a second conductor line disposed in a second one of the conductor layers and different from the first conductor layer; a first via penetrating the base, electrically connecting the first conductor line and the second conductor line, and having a via stub; and a third conductor line disposed in a vicinity of the first via in a plane parallel to the first via and having a closed ring shape.

### CROSS-REFERENCE TO RELATED APPLICATION

This application is based upon and claims the benefit of priority from Japanese Patent Application No. 2025-047258, filed Mar. 21, 2025, the entire contents of which are incorporated herein by reference.

### FIELD

Embodiments described herein relate generally to a substrate and an electronic device.

### BACKGROUND

A printed circuit board (PCB) and a package substrate (PKG substrate) are known as substrates having a plurality of conductor layers. Such a substrate may have a through-via. The through-via functions as a part of a transmission line that connects different conductor layers of the substrate. The through-via penetrates from a front surface of the substrate to a rear surface thereof to achieve connection between a plurality of conductor layers, but depending on a circuit configuration on the substrate, the entire through-via from an end portion on a front surface side of the substrate to an end portion on a rear surface side of the substrate may not be used.

For example, when the through-via connects a transmission line formed by the conductor layer disposed on the front surface of the substrate and a transmission line formed by the conductor layer disposed inside the substrate to form an integral transmission line, a portion of the through-via from the transmission line inside the substrate to a rear surface of the substrate does not function as the transmission line. In this manner, a surplus portion of the through-via that is not intended to function as the transmission line may become a via stub and may cause an unexpected resonance point, and may be a cause of deterioration of frequency characteristics of the transmission line.

The via stub may generally be cut by a back drill, but an additional process and cost are incurred. Furthermore, the back drill needs to be performed as a last step after forming all wirings is completed, which causes corrosion and a decrease in durability.

### DESCRIPTION OF THE DRAWINGS

FIG. 1 is a diagram showing a configuration example of a transmission line of a first embodiment.

FIG. 2 is a circuit diagram showing an equivalent circuit of the transmission line of the first embodiment.

FIG. 3 is a diagram showing a resonance point generated in the transmission line of the first embodiment.

FIG. 4 is a diagram showing a first specific example of the transmission line of the first embodiment in a perspective manner.

FIG. 5 is a diagram showing a second specific example of the transmission line of the first embodiment in a perspective manner.

FIG. 6 is a diagram showing a configuration example of a transmission line of a second embodiment.

FIG. 7 is a circuit diagram showing an equivalent circuit of the transmission line of the second embodiment.

FIG. 8 is a block diagram showing a functional configuration of an electronic device according to a third embodiment.

FIG. 9 is a diagram showing a transmission line of a comparative example in a perspective manner.

FIG. 10 is a diagram showing a configuration example of the transmission line of the comparative example.

FIG. 11 is a conceptual diagram showing an equivalent circuit of the transmission line of the comparative example.

FIG. 12 is a circuit diagram showing the equivalent circuit of the transmission line of the comparative example.

FIG. 13 is a diagram showing a resonance point generated in the transmission line of the comparative example.

### DETAILED DESCRIPTION

Embodiments provide a substrate and an electronic device capable of improving deterioration of frequency characteristics that may be caused by a through-via.

In general, according to one embodiment, a substrate includes a base; and a transmission line disposed on or in a base, and formed as a part of a plurality of conductor layers. The transmission line includes: a first conductor line disposed in a first one of the conductor layers; a second conductor line disposed in a second one of the conductor layers and different from the first conductor layer; a first via penetrating the base, electrically connecting the first conductor line and the second conductor line, and having a via stub; and a third conductor line disposed in a vicinity of the first via in a plane parallel to the first via and having a closed ring shape.

### Comparative Example

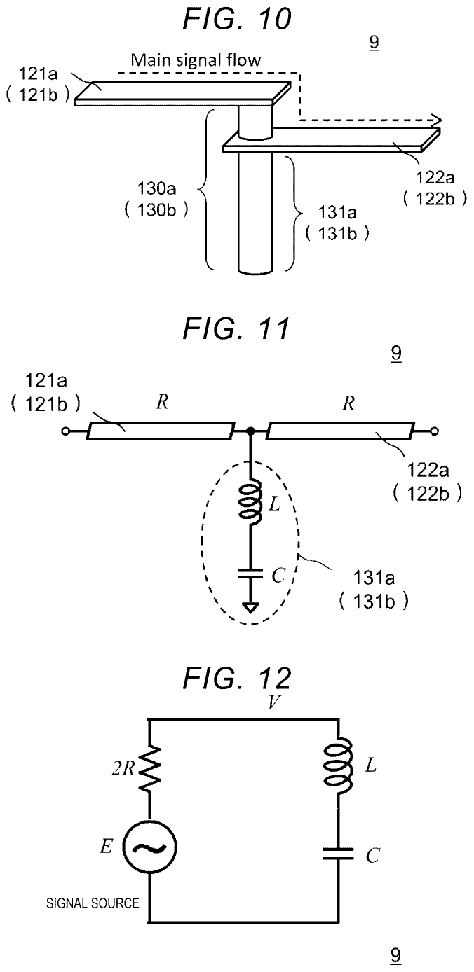

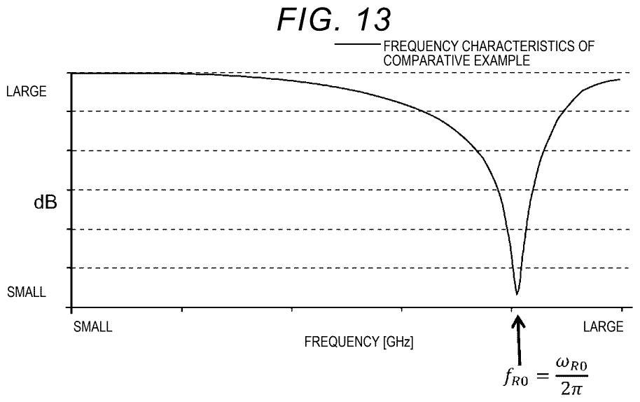

A transmission line formed on a base in a substrate of a comparative example will be described with reference to FIGS. 9 to 13. The transmission line includes a through-via. FIG. 9 is a diagram showing the transmission line of the comparative example in a perspective manner. FIG. 10 is a diagram showing a configuration example of the transmission line of the comparative example. FIG. 11 is a conceptual diagram showing an equivalent circuit of the transmission line of the comparative example. FIG. 12 is a circuit diagram showing the equivalent circuit of the transmission line of the comparative example. FIG. 13 is a diagram showing a resonance point generated in the transmission line of the comparative example. In the following description, the same components are denoted by the same reference numerals, and redundant description is omitted.

FIGS. 9 and 10 show an example of a transmission line 9. As shown in FIGS. 9 and 10, the transmission line 9 has conductor lines 121a and 121b, conductor lines 122a and 122b, and through-vias 130a and 130b. The conductor lines 121a and 121b are disposed in the same plane as a conductor layer formed on a front surface of a base 91 (a part of a substrate 90) made of a dielectric material or the like. The conductor lines 122a and 122b are disposed in the same plane as a conductor layer formed inside the base 91. Through-vias 130a and 130b include conductors that penetrate from the front surface of the base 91 to a rear surface thereof and are electrically connected to the conductor lines 121a and 121b, and the conductor lines 122a and 122b, respectively. In the example shown in FIG. 9, the through-vias 130a and 130b are not connected to the lines formed of the conductor layer on a rear surface side of the base 91. That is, portions from connection points of the lines 122a and 122b in the through-vias 130a and 130b to the rear surface of the base 91 are each formed with via stubs 131a and 131b. The conductor lines 121a, 121b, 122a, and 122b, and the through-vias 130a and 130b are made of a conductor material such as copper or silver, for example.

The transmission line 9 shown in FIG. 9 is a differential line in which two transmission lines are paired, one of the two lines being formed of the conductor line 121a, the through-via 130a, and the conductor line 122a, and the other of the two lines being formed of the conductor line 121b, the through-via 130b, and the conductor line 122b. However, in the following description, one line (the conductor line 121a, the through-via 130a, and the conductor line 122a) is described for convenience. In the transmission line 9 shown in FIG. 10, an electrical signal flows, for example, in the order of the conductor line 121a, the through-via 130a, and the conductor line 122a. Although the via stub 131a is not located on the path through which the electrical signal flows, the via stub 131a behaves as a distributed constant circuit, particularly when the frequency of the electrical signal is high. As shown in FIG. 11, the via stub 131a may be regarded as a distributed constant circuit having an inductance component L and a capacitance component C.

As shown in FIG. 12, the transmission line 9 is a distributed constant circuit including a resistance component 2R, the inductance component L, and the capacitance component C when viewed from a signal source E. An angular frequency φ_{R0} of a resonance point of the circuit by the inductance component L and the capacitance component C is represented by the following.

$${ω}_{R 0} = \frac{1}{\sqrt{LC}} \qquad ( 1 )$$

Here, ω_{R0} is 2πf_{R0}, and f_{R0} is a resonance frequency of the transmission line 9 including the via stub 131a (131b).

FIG. 13 shows frequency characteristics of the equivalent circuit shown in FIG. 12 in the transmission line 9. As shown in FIG. 13, the transmission line 9 has a large attenuation point at the resonance frequency f_{R0}. This leads to a deterioration in the frequency characteristics of the transmission line 9. The transmission line according to the embodiment may improve the deterioration of the frequency characteristics due to the resonance point.

### First Embodiment

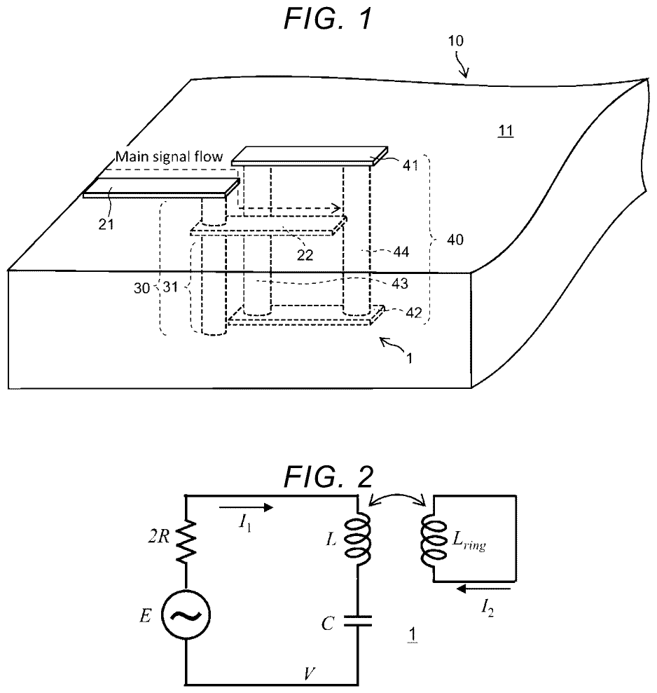

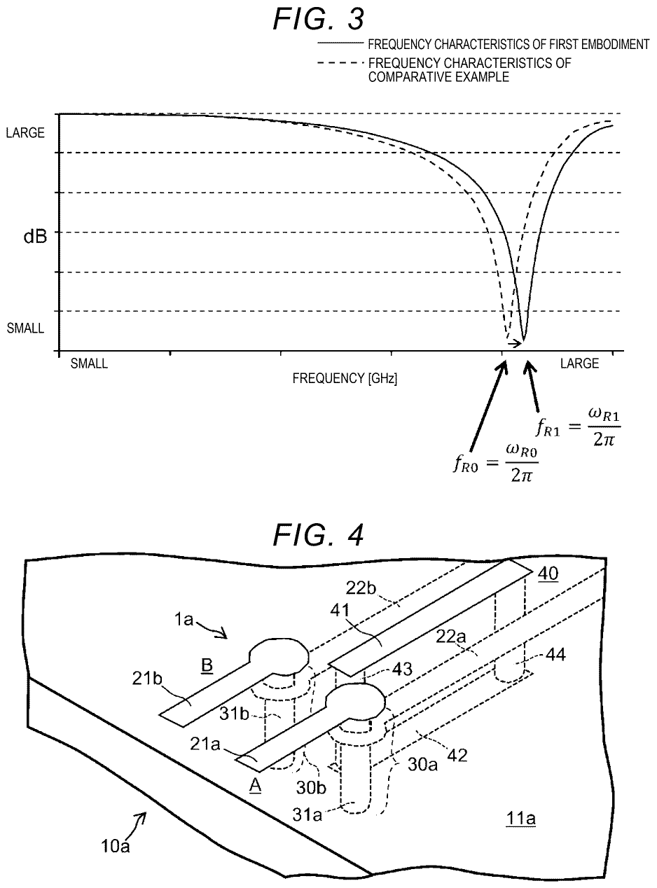

Hereinafter, a transmission line formed on a base in a substrate of a first embodiment will be described in detail with reference to the drawings. FIG. 1 is a diagram showing a configuration example of the transmission line of the first embodiment. FIG. 2 is a circuit diagram showing an equivalent circuit of the transmission line of the first embodiment. FIG. 3 is a diagram showing a resonance point generated in the transmission line of the first embodiment. In the following description, the same reference numerals are used to denote the functional elements that are common to the transmission line of the comparative example, and the description thereof is omitted.

As shown in FIG. 1, a transmission line 1 of the first embodiment has a conductor line 21, a conductor line 22, and a through-via 30. The conductor line 21 is disposed in the same plane as a conductor layer formed on a front surface of a base 11 (a part of a substrate 10) made of a dielectric material or the like. The conductor line 22 is disposed in the same plane as a conductor layer disposed in the base 11. A through-via 30 includes a conductor that penetrates from the front surface of the base 11 to a rear surface thereof. The through-via 30 penetrates from the front surface of the base 11 to the rear surface thereof to connect the conductor line 21 and the conductor line 22, but is not connected to the conductor line or the like formed in the same plane as a conductor layer formed on the rear surface of the base 11. That is, a portion of the through-via 30 from a connection point to the conductor line 22 inside the base 11 to the rear surface of the base 11 is configured as a via stub 31.

The transmission line 1 of the first embodiment further has a ring-shaped conductor line 40 at a position adjacent to the via stub 31. The conductor line 40 has a conductor line 41, a through-via 43, a conductor line 42, and a through-via 44.

The conductor line 41 is made of a conductor layer formed in a plane parallel to the front surface of the base 11. In the example shown in FIG. 1, the conductor line 41 is disposed on the front surface of the base 11, that is, in the same plane as the conductor line 21, but the present disclosure is not limited thereto. The conductor line 41 may be formed inside the base 11 by a conductor layer formed in a plane parallel to the front surface of the base 11.

The conductor line 42 is made of a conductor layer formed in a plane parallel to the rear surface of the base 11. In the example shown in FIG. 1, the conductor line 42 is disposed on the rear surface of the base 11, but the present disclosure is not limited thereto. The conductor line 42 may be disposed inside the base 11 parallel to and in a plane different from the conductor line 41.

The through-via 43 is a via made of a conductor material that electrically connects one end of the conductor line 41 to one end of the conductor line 42. The through-via 44 is a via made of a conductor material that electrically connects the other end of the conductor line 41 to the other end of the conductor line 42. That is, the conductor line 41, the through-via 43, the conductor line 42, and the through-via 44 are connected in this order to form the ring-shaped conductor line 40. The conductor line 40 is disposed in the vicinity of the through-via 30 (the via stub 31) in a plane parallel to the through-via 30 and has a closed ring shape.

FIG. 2 shows the equivalent circuit of the transmission line 1 of the first embodiment. As shown in FIG. 2, a part of the transmission line 1 is a distributed constant circuit including the resistance component 2R, the inductance component L, and the capacitance component C, when viewed from the signal source E. In addition, in the transmission line 1 of the first embodiment, a circuit is configured in which the inductance component L of the via stub 31 and an inductance component L_{ring} of the conductor line 40 are magnetically coupled. An angular frequency ω_{R1} of the resonance point of the transmission line 1 shown in FIG. 2 is represented by the following.

$${ω}_{R1} = \frac{1}{\sqrt{C ( L − \frac{{M}^{2}}{{L}_{ring}} )}} = \frac{1}{\sqrt{L C ( 1 − {k}^{2} )}} \qquad ( 2 )$$

$$M = k \sqrt{{LL}_{ring}}$$

Here, M is mutual inductance, and k is a coupling coefficient (1>k>0).

As shown in (2), the conductor line 40 is provided at a position adjacent to the via stub 31, so that the angular frequency ω_{R1} is shifted to a large value. The angular frequency ω_{R1} is 2πf_{R1}, and f_{R1} is the resonance frequency of the transmission line 1 of the first embodiment. That is, the resonance frequency is shifted in a direction higher than that of the comparative example.

FIG. 3 shows the frequency characteristics of the transmission line 1 having the conductor line 40 and the frequency characteristics of the transmission line 9 of the comparative example not having the conductor line 40. As shown in FIG. 3, since the transmission line 1 of the first embodiment includes the ring-shaped conductor line 40 at a position adjacent to the via stub 31, the attenuation point of the frequency characteristics may be shifted and the deterioration of the frequency characteristics may be prevented.

In the example described above, the conductor line 21 is formed on the front surface of the base 11 and the conductor line 22 is disposed in the base 11, but the present disclosure is not limited thereto. Both the conductor line 21 and the conductor line 22 may be disposed inside the base 11. That is, the configuration of the first embodiment may be applied in the same manner even when the via stub is generated on both the front surface side of the base 11 and the rear surface side thereof.

In addition, in the example described above, the conductor line 40 is formed by the conductor line 41 disposed on the front surface of the base 11, the through-vias 43, the conductor line 42 disposed on the rear surface of the base 11, and the through-vias 44, but the present disclosure is not limited thereto. Both or either one of the conductor line 41 and the conductor line 42 may be disposed inside the base 11. That is, the position and the shape of the conductor line 40 are not limited as long as the conductor line 40 has an effect of being magnetically coupled to the via stub 31 and increasing the resonance frequency.

### Specific Examples of First Embodiment

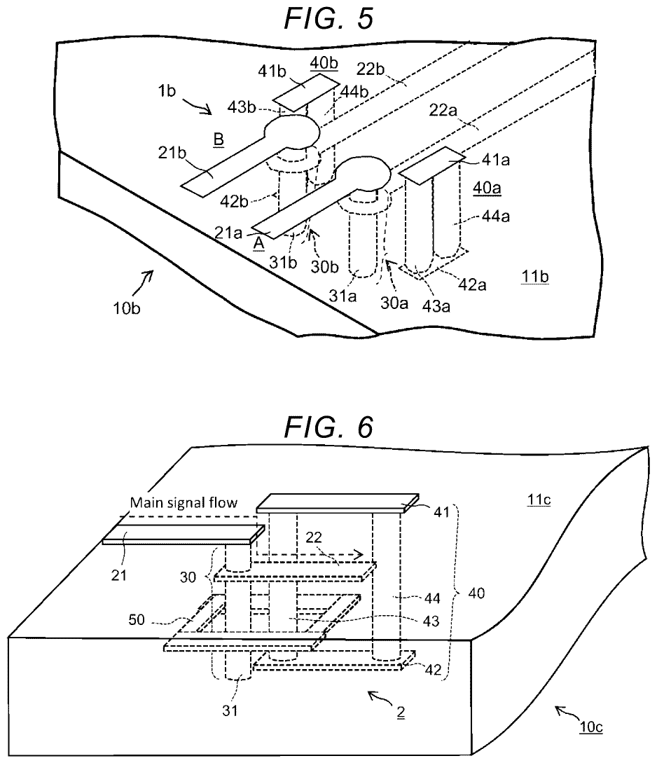

Next, a specific example of the transmission line in the first embodiment will be described with reference to FIG. 4. FIG. 4 is a diagram showing a first specific example of the transmission line of the first embodiment in a perspective manner. FIG. 5 is a diagram showing a second specific example of the transmission line of the first embodiment in a perspective manner.

A transmission line 1a shown in FIG. 4 is configured such that a conductor line A having a path including a conductor line 21a, a through-via 30a, and a conductor line 22a, and a conductor line B having a path including a conductor line 21b, a through-via 30b, and a conductor line 22b are paired to be disposed parallel to each other in a base 11a on a substrate 10a, and is capable of transmitting a differential signal. The line A has a via stub 31a, and the line B has a via stub 31b.

The transmission line 1a includes a ring-shaped conductor line 40 in which the conductor line 41, the through-via 43, the conductor line 42, and the through-via 44 are connected in this order in the vicinity of both the via stub 31a of the conductor line A and the via stub 31b of the conductor line B. That is, a circuit having an inductance component that is magnetically coupled to both the inductance component of the via stub 31a and the inductance component of the via stub 31b is formed. In the example shown in FIG. 4, the conductor line 40 is disposed in a plane between the through-via 30a and the through-via 30b parallel to each of the through-via 30a and the through-via 30b.

According to the first specific example of the first embodiment, the ring-shaped conductor line is disposed between the pair of transmission lines, so that the deterioration of the frequency characteristics may be prevented without providing a special wiring space.

A transmission line 1b shown in FIG. 5 is configured such that a conductor line A having a path including the conductor line 21a, the through-via 30a, and the conductor line 22a and a conductor line B having a path including the conductor line 21b, the through-via 30b, and the conductor line 22b are paired to be disposed parallel to each other in a base 11b on a substrate 10b, and is capable of transmitting a differential signal. The line A has a via stub 31a, and the line B has a via stub 31b.

The transmission line 1b has a conductor line 40a disposed at a position in the vicinity of the via stub 31a of the conductor line A on the opposite side of the conductor line B with the conductor line A interposed therebetween. In addition, the transmission line 1b has a conductor line 40b disposed at a position in the vicinity of the via stub 31b of the conductor line B on the opposite side of the conductor line A with the conductor line B interposed therebetween. As shown in FIG. 5, the conductor line 40a is a ring-shaped conductor line in which the conductor line 41a, the through-via 43a, the conductor line 42a, and the through-via 44a are connected in this order. In addition, the conductor line 40b is a ring-shaped conductor line in which the conductor line 41b, the through-via 43b, the conductor line 42b, and the through-via 44b are connected in this order. That is, a circuit of the conductor line 40a magnetically coupled to the inductance component of the via stub 31a and a circuit of the conductor line 40b magnetically coupled to the inductance component of the via stub 31b are formed. In the example shown in FIG. 5, the conductor line 40a is disposed in a plane on the opposite side of the through-via 30b with the through-via 30a interposed therebetween, parallel to each of the through-via 30a and the through-via 30b. Similarly, the conductor line 40b is disposed in a plane on the opposite side of the through-via 30a with the through-via 30b interposed therebetween, parallel to each of the through-via 30a and the through-via 30b.

According to the second specific example of the first embodiment, since the ring-shaped conductor line that is individually and magnetically coupled to each of the via stubs of each of the transmission lines constituting a pair is disposed, the deterioration of the frequency characteristics may be more precisely prevented.

### Second Embodiment

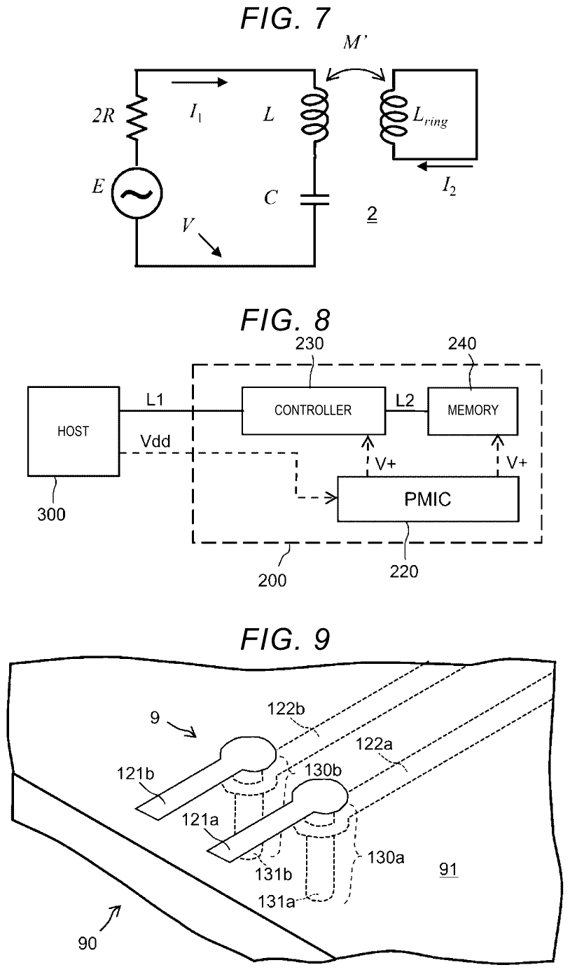

Next, a transmission line disposed on a base in a substrate of a second embodiment will be described with reference to FIGS. 6 and 7. FIG. 6 is a diagram showing a configuration example of the transmission line of the second embodiment. FIG. 7 is a circuit diagram showing an equivalent circuit of the transmission line of the second embodiment. The transmission line of the second embodiment is obtained by adding a coupling circuit to the transmission line of the first embodiment. In the following description, the same reference numerals are given to the functional elements common to the first embodiment, and the description thereof is omitted.

As shown in FIG. 6, a transmission line 2 of the second embodiment has a conductor line 21, a conductor line 22, and a through-via 30. The conductor line 21 is disposed in the same plane as the conductor layer disposed on a front surface of a base 11c (a part of a substrate 10c). The conductor line 22 is disposed in the same plane as the conductor layer disposed in the base 11c. The through-via 30 includes a conductor that penetrates from the front surface of the base 11c to the rear surface thereof. The through-via 30 penetrates from the front surface of the base 11c toward the rear surface thereof to connect the conductor line 21 and the conductor line 22, but is not connected to the conductor line or the like formed in the same plane as the conductor layer formed on the rear surface of the base 11c. That is, a portion of the through-via 30 from a connection point of the conductor line 22 inside the base 11c to the rear surface of the base 11c configures the via stub 31.

The transmission line 2 of the second embodiment has a ring-shaped conductor line 40 at a position adjacent to the via stub 31. The conductor line 40 has a conductor line 41, a through-via 43, a conductor line 42, and a through-via 44.

The conductor line 41 is made of a conductor layer formed in a plane parallel to the front surface of the base 11c. The conductor line 42 is made of a conductor layer formed in a plane parallel to the rear surface of the base 11c. The through-via 43 is a via made of a conductor material that electrically connects one end of the conductor line 41 to one end of the conductor line 42. The through-via 44 is a via made of a conductor material that electrically connects the other end of the conductor line 41 to the other end of the conductor line 42. That is, the conductor line 41, the through-via 43, the conductor line 42, and the through-via 44 are connected in this order to form the ring-shaped conductor line 40.

The transmission line 2 of the second embodiment further has a coupling circuit 50 formed in a ring-shaped conductor line and made of a conductor layer. In the example shown in FIG. 6, the coupling circuit 50 is a functional element that magnetically couples the via stub 31 and the ring-shaped conductor line 40. The coupling circuit 50 shown in FIG. 6 has a rectangular shape in which two conductor lines extending in the same direction as the conductor line 21 that are disposed in the same plane as the conductor layer between the conductor line 22 and the conductor line 42, and two conductor lines extending in a direction orthogonal to the conductor line 21 that are disposed in the same plane as the two conductor lines are connected. The coupling circuit 50 has a ring shape surrounding the via stub 31 and the through-via 43.

In the example shown in FIG. 6, the coupling circuit 50 has a rectangular shape when viewed in the plane direction of the base 11c, but the present disclosure is not limited thereto. The coupling circuit 50 may have a circular shape or the like as long as an aspect of magnetically coupling the via stub 31 and the line (conductor line 40) having a ring shape. In addition, in the example shown in FIG. 6, the coupling circuit 50 surrounds the via stub 31 and the through-via 43, but the present disclosure is not limited thereto. The coupling circuit 50 may surround the via stub 31 and the through-vias 43 and 44. In addition, in the example shown in FIG. 6, the coupling circuit 50 is formed in a layer parallel to a main surface of the base 11c, but the present disclosure is not limited thereto. The coupling circuit 50 may have a via that interconnects layers on its path.

In addition, in the example shown in FIG. 6, the coupling circuit 50 is added to the transmission line 1 of the first embodiment shown in FIG. 1, but the present disclosure is not limited thereto. The coupling circuit 50 may be added to the transmission lines 1a and 1b according to the specific example of the first embodiment shown in FIGS. 4 and 5. For example, in the transmission line 1a shown in FIG. 4, a ring-shaped conductor line, which surrounds the via stub 31a of the conductor line A, the via stub 31b of the conductor line B, and the through-via 43 of the conductor line 40, may be disposed. In addition, in the transmission line 1b shown in FIG. 5, a ring-shaped conductor line that surrounds the via stub 31a of the conductor line A and the through-via 43a of the conductor line 40a, and a ring-shaped conductor line that surrounds the via stub 31b of the conductor line B and the through-via 43b of the conductor line 40b may be disposed.

FIG. 7 shows the equivalent circuit of the transmission line 2 of the second embodiment. As shown in FIG. 7, a part of the transmission line 2 is a distributed constant circuit including the resistance component 2R, the inductance component L, and the capacitance component C, when viewed from the signal source E. In addition, in the transmission line 2 of the second embodiment, the inductance component L of the via stub 31 and the inductance component L_{ring} of the ring-shaped conductor line 40 are magnetically coupled to each other, and a circuit in which the degree of coupling is further increased by the coupling circuit 50 is configured. The angular frequency ω_{R2} of the resonance point of the transmission line 2 shown in FIG. 7 is represented by the following.

$${ω}_{R 2} = \frac{1}{\sqrt{C ( L − \frac{{M}^{′ 2}}{{L}_{ring}} )}} = \frac{1}{\sqrt{L C ( 1 − {k}^{′ 2} )}} \qquad ( 3 )$$

$${M}^{′} = {k}^{′} \sqrt{{LL}_{ring}}$$

Here, M′ is mutual inductance, and k′ is a coupling coefficient (1>k′>k>0).

As shown in (3), the coupling coefficient k′ of the transmission line 2 of the second embodiment having the coupling circuit 50 is larger than the coupling coefficient k of the transmission line 1 of the first embodiment not having the coupling circuit 50. That is, the angular frequency ω_{R2} is shifted to a larger value than the angular frequency ω_{R1} in the first embodiment. The angular frequency ωR2 is 2πfR2, and fR2 is a resonance frequency of the transmission line 2 of the second embodiment. That is, the resonance frequency is shifted in a direction higher than that of the first embodiment. Therefore, the transmission line 2 of the second embodiment may obtain a higher frequency of an attenuation point in a frequency characteristic as, and thus achieves a higher band extension effect, compared with the transmission line 1 of the first embodiment.

According to the transmission lines of the first and second embodiments, each of the two ring-shaped conductor lines is disposed in the vicinity of the through-via, so that the operation frequency may be extended at low cost. Furthermore, since it is not necessary to make a hole in the substrate, the problems of corrosion and durability are solved.

### Third Embodiment

As shown in FIG. 8, an electronic device 200 of a third embodiment configures a memory system. The electronic device 200 includes a power management IC (PMIC) 220, a controller 230, and a memory 240. The power management IC 220, the controller 230, and the memory 240 are each an example of a semiconductor component. The electronic device 200 may be connected to a host 300 via a signal line L1 and a power supply wiring Vdd. The signal line L1 is, for example, a bus line that communicates signals between the electronic device 200 and the host 300. The wiring on the electronic device 200 provided between the signal line L1 and the controller 230 may be applied with the transmission line 1 of the first embodiment or the transmission line 2 of the second embodiment. The power supply wiring Vdd is, for example, a power supply line capable of supplying a predetermined voltage from the host 300 to the electronic device 200.

The controller 230 is a circuit element that receives a command from the host 300 and realizes functions such as reading, writing, and erasing data to and from the memory 240. The controller 230 is an electronic circuit including, for example, a processor to realize the above-described functions, and is configured as, for example, an SoC. The memory 240 is a semiconductor storage device including, for example, a NAND flash memory. The memory 240 is connected to the controller 230 by a bus line including, for example, a signal line L2 based on a predetermined standard. The signal line L2 may be applied with the transmission line 1 of the first embodiment or the transmission line 2 of the second embodiment.

The PMIC 220 is a circuit element capable of generating a plurality of output voltages having different voltage values. The PMIC 220 receives a predetermined voltage supplied from the host 300 via the power supply wiring Vdd to generate various output voltages V+ and the like, and supplies the various output voltages V+ and the like to the controller 230, the memory 240, and the like.

According to the electronic device 200 of the third embodiment, since the transmission line 1 of the first embodiment or the transmission line 2 of the second embodiment is provided as the signal line, the frequency characteristics of the signal transmission may be improved.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A substrate, comprising:
a base; and
a transmission line disposed on or in a base, and formed as a part of a plurality of conductor layers;
wherein the transmission line includes:
a first conductor line disposed in a first one of the conductor layers;
a second conductor line disposed in a second one of the conductor layers and different from the first conductor layer;
a first via penetrating the base, electrically connecting the first conductor line and the second conductor line, and having a via stub; and
a third conductor line disposed in a vicinity of the first via in a plane parallel to the first via and having a closed ring shape.

2. The substrate according to claim 1, wherein the first conductor line is disposed on a front surface of the base or in the base.

3. The substrate according to claim 1, wherein the third conductor line includes:
a fourth conductor line formed on one main surface of the base;
a fifth conductor line formed on the other main surface of the base; and
a second via and a third via each penetrating a part of the base and connecting the fourth conductor line and the fifth conductor line.

4. The substrate according to claim 1, further comprising:
a sixth conductor line disposed adjacent to the first conductor line and parallel to the first conductor line;
a seventh conductor line disposed adjacent to the second conductor line and parallel to the second conductor line; and
a fourth via penetrating a part of the base, electrically connecting the sixth conductor line and the seventh conductor line, and having a via stub,
wherein the third conductor line is parallel to each of the first via and the fourth via, and disposed in a plane between the first via and the fourth via.

5. The substrate according to claim 1, further comprising:
a sixth conductor line disposed adjacent to the first conductor line and parallel to the first conductor line;
a seventh conductor line disposed adjacent to the second conductor line and parallel to the second conductor line; and
a fourth via penetrating a part of the base, electrically connecting the sixth conductor line and the seventh conductor line, and having a via stub,
wherein the third conductor line is parallel to each of the first via and the fourth via, and disposed in a plane on an opposite side of the fourth via with the first via interposed therebetween.

6. The substrate according to claim 5, further comprising:
an eighth conductor line disposed in a vicinity of the fourth via in a plane parallel to the fourth via and having a closed ring shape; and
wherein the eighth conductor line is parallel to each of the first via and the fourth via, and disposed in a plane on an opposite side of the first via with the fourth via interposed therebetween.

7. The substrate according to claim 6, wherein the eighth conductor line includes:
a ninth conductor line formed on one main surface of the base;
a tenth conductor line formed on the other main surface of the base; and
a fifth via and a sixth via each penetrating a part of the base and connecting the ninth conductor line and the tenth conductor line.

8. The substrate according to claim 1, further comprising:
an eleventh conductor line formed in a ring shape surrounding each of the first via and a part of the third conductor line.

9. The substrate according to claim 8, wherein the eleventh conductor line is configured to surround the via stub of the first via.

10. The substrate according to claim 8, wherein the eleventh conductor line is disposed in a third one of the conductor layers, which is different from both the first one and the second one.

11. An electronic device comprising:
the transmission line disposed on the substrate according to claim 1; and
a semiconductor component that is connected to the transmission line.

12. An electronic device comprising:
the transmission line disposed on the substrate according to claim 2; and
a semiconductor component that is connected to the transmission line.

13. An electronic device comprising:
the transmission line disposed on the substrate according to claim 3; and
a semiconductor component that is connected to the transmission line.

14. An electronic device comprising:
the transmission line disposed on the substrate according to claim 4; and
a semiconductor component that is connected to the transmission line.

15. An electronic device comprising:
the transmission line disposed on the substrate according to claim 5; and
a semiconductor component that is connected to the transmission line.

16. An electronic device comprising:
the transmission line disposed on the substrate according to claim 6; and
a semiconductor component that is connected to the transmission line.

17. An electronic device comprising:
the transmission line disposed on the substrate according to claim 7; and
a semiconductor component that is connected to the transmission line.

18. An electronic device comprising:
the transmission line disposed on the substrate according to claim 8; and
a semiconductor component that is connected to the transmission line.

19. An electronic device comprising:
the transmission line disposed on the substrate according to claim 9; and
a semiconductor component that is connected to the transmission line.

20. An electronic device comprising:
the transmission line disposed on the substrate according to claim 10; and
a semiconductor component that is connected to the transmission line.
